(19) United States
(12) Patent Application Publication
(10) Pub. No.: US 2024/0204083 A1
(43) Pub. Date: Jun. 20, 2024

(54) DSA (DIRECTED SELF-ASSEMBLY) BASED SPACER AND LINER FOR SHORTING MARGIN OF VIA

(71) Applicant: Intel Corporation, Santa Clara, CA (US)

(72) Inventors: Gurpreet Singh, Portland, OR (US); Manish Chandhok, Beaverton, OR (US); Florian Gstrein, Portland, OR (US); Charles Henry Wallace, Portland, OR (US); Eungnak Han, Portland, OR (US); Leonard P. Guler, Hillsboro, OR (US)

(73) Assignee: Intel Corporation, Santa Clara, CA (US)

(21) Appl. No.: 18/066,307

(22) Filed: Dec. 15, 2022

(51) Int. Cl. H01L 29/66; H01L 21/768; H01L 21/8234; H01L 23/00; H01L 23/498; H01L 25/065

(52) U.S. Cl. CPC H01L 29/6656; H01L 21/76897; H01L 21/823475; H01L 23/49816; H01L 24/16; H01L 25/0655; H01L 29/66545; H01L 2224/16227; H01L 2224/48091; H01L 2924/15311

(57) ABSTRACT

DSA-based spacers and liners can provide shorting margins for vias connected to conductive structures. Self-assembly of a diblock copolymer may be performed over a layer including conductive structures and insulative structures separating the conductive structures from each other. Spacers may be formed based on the self-assembly of the diblock copolymer. Each spacer includes an electrical insulator and is over an insulative structure. Each liner may wrap around one or more side surfaces of a spacer. Each pair of spacer and liner constitutes an insulative spacing structure that provides a shorting margin to avoid short between a via and a conductive structure not connected to the via. The insulative spacing structures may include a different electrical insulator from the insulative structures. The conductive structures may be arranged in parallel along a direction and have the same or similar heights in the direction and function as different contacts of a device.

### BACKGROUND

IC (integrated circuit) fabrication usually includes two stages. The first stage is referred to as the front end of line (FEOL). The second stage is referred to as the back end of line (BEOL). In the FEOL, individual components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device comprising an FEOL section and a BEOL section, according to some embodiments of the disclosure.

FIG. 2 illustrates DSA of a diblock copolymer, according to some embodiments of the disclosure.

FIG. 3 illustrates formation of openings based on a DSA pattern, according to some embodiments of the disclosure.

FIG. 4 illustrates formation of spacers, according to some embodiments of the disclosure.

FIG. 5 illustrates formation of openings that separate spacers, according to some embodiments of the disclosure.

FIG. 6 illustrates formation of liners, according to some embodiments of the disclosure.

FIG. 7 illustrates vias separated from metal lines through spacers and liners, according to some embodiments of the disclosure.

FIGS. 8A-8B are top views of a wafer and dies that may include DSA-based spacers and liners, according to some embodiments of the disclosure.

FIG. 9 is a side, cross-sectional view of an example IC package that may include one or more IC devices having DSA-based spacers and liners, according to some embodiments of the disclosure.

FIG. 10 is a cross-sectional side view of an IC device assembly that may include components having one or more IC devices implementing DSA-based spacers and liners, according to some embodiments of the disclosure.

FIG. 11 is a block diagram of an example computing device that may include one or more components with DSA-based spacers and liners, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Continued scaling of transistors and design cell height leads to narrow BEOL metal lines. This creates a challenge for metal patterning, via landing, or edge placement error control and the need to ensure low resistance of metal lines and vias. Taking vias connected to FEOL transistors and M0 for example, shorting margin of VCG and VCT is usually achieved through metal recess of GCN and TCN in M0. VCG is via connecting gate, such as a via connected or coupled to the gate electrode of a transistor. VCT is via connecting transistor, such as a via connected or coupled to the source contact or drain contact of a transistor. VCG may be connected to GCN, which is gate contact (e.g., gate electrode) or a metal line in a metal layer (e.g., M0, M1, etc.) that is coupled to the gate of the transistor. VCT may be connected to TCN, which is trench contact (e.g., source or drain contact of the transistor) or a metal line in metal layer (e.g., M0, M1, etc.) that is coupled to the source or drain contact of the transistor. As the gate electrode is usually at a different electrical potential from the source contact or drain contact, VCG needs to be insulated from TCN. Also, VCT needs to be insulated from GCN. The purpose of metal recess to provide a sufficient distance (i.e., a sufficient shorting margin) between VCG and TCN or between VCT and GCN.

However, a challenge of metal recess is that metal recess is not controllable. For instance, the amount of metal removed during a metal recess process can be difficult to control. This can lead to variations in metal line dimensions or surface smoothness, which can degrade performance of the IC device. Also, through metal recess, the electrical insulator between VCG and TCN or between VCT and GCN is usually the same material as the electrical insulator between the metal lines, e.g., ILD (interlayer dielectric). There is hardly any other material choice. Given the fallbacks of metal recess, improvement technologies for providing shorting margin of vias are needed.

Embodiments of the present disclosure may improve on at least some of the challenges and issues described above by providing DSA-based spacers and liners to improve shorting margins of vias. In various embodiments of the present disclosure, a DSA layer is formed over an underlayer including conductive structures and insulative structures. The conductive structures may be used as contacts of a semiconductor device in a FEOL section, such as the gate contact, source contact, and drain contact of a transistor. Alternatively, the conductive structures may be used as metal lines in a BEOL section, such as metal lines in M0, M1, M2, etc. The DSA layer may be formed through self-assembly of a diblock copolymer. The diblock copolymer may include two types of monomers: A and B. The diblock copolymer may have a phase (e.g., a lamellar phase) that has a periodic distribution of A and B. The self-assembly of a diblock copolymer produces an alternating pattern of polymer A and polymer B. One of the polymers can be removed from the DSA layer to create openings in the DSA layer. One or more electrical insulators can be provided into the openings to form the spacers. The spacers may include one or more different materials from the insulative structures in the BEOL layer.

Liners can be formed around the spacers. For example, an electrical insulator may be provided to form a liner wrapping around a spacer at least partially. The liner may surround one or more side surfaces of the spacer. In some embodiments, a side surface of the space may extend in a direction that is perpendicular or substantially perpendicular to the underlayer or a substrate. Each pair of liner and spacer can form an insulative spacing structure for providing a shorting margin of vias connected to the conductive structures. As the spacers are formed based on the self-alignment of the diblock copolymer, the spacers may be aligned with the insulative structures in the underlayer. Each spacer may be over an insulative structure in the layer. The liner around the spacer may be over one or more conductive structures in the underlayer. A via can be placed at least partially between two adjacent insulative spacing structures and connected to a conductive structure in the underlayer. The via can be separated from one or more other conductive structures in the underlayer (e.g., conductive structures that are adjacent to the conductive structure connected to the via) through the insulative spacing structures. Despite that the conductive structures in the underlayer may have the same height, the insulative spacing structures can sufficient shorting margin to avoid shorting between the via and the other conductive structures that are not connected to the via.

With the DSA-based spacers and liners in the present disclosure, metal recess can be avoided so that the fallbacks of metal recess can be avoided. The DSA process for forming the spacers and liners is more controller than metal recess. It also allows independent material choice so that the spacers and liners can have different materials from the electrical insulator between the metal lines or can have different materials from each other. Additionally, compared with metal recess, the DSA-based spacers and liners does not reduce the heights of contacts or metal lines and therefore, can facilitate fabrication of taller devices with lower resistance, such as taller memory devices (e.g., static random-access memory (SRAM)). Therefore, the present disclosure provides a more advantageous technology for providing shorting margins of vias than the currently available technologies.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

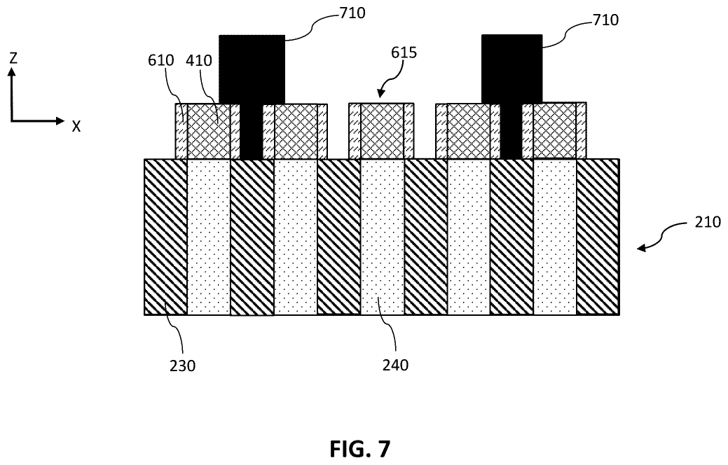

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of DSA-based spacers and liners as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various DSA-based spacers and liners as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

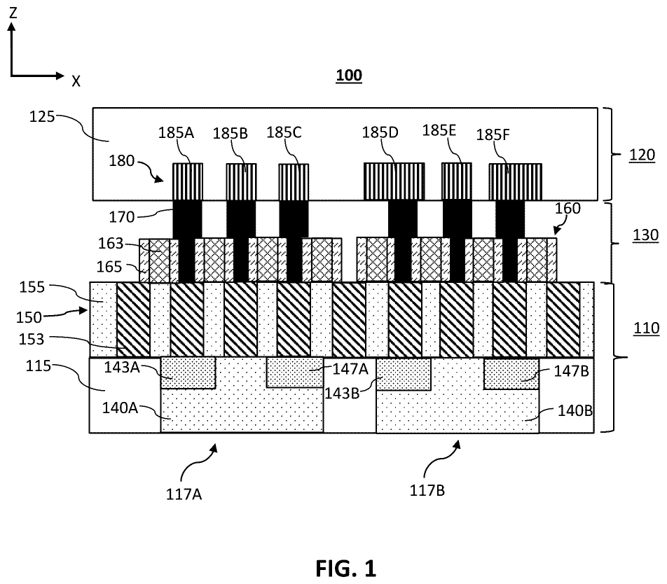

FIG. 1 illustrates an IC device 100 comprising an FEOL section 110 and a BEOL section 120, according to some embodiments of the disclosure. As shown in FIG. 1, the FEOL section 110 includes a support structure 115, two transistors 117A and 117B (collectively referred to as “transistors 117” or “transistor 117”), and a layer 150 that includes conductive structures 153 (individually referred to as “conductive structure 153”) and insulative structures 155 (individually referred to as “insulative structure 155”). The BEOL section 120 includes an electrical insulator 125 and a metal layer 180 that includes metal lines 185A-185F (collectively referred to as “metal lines 185” or “metal line 185”). The IC device 100 also includes an intermediate layer 130 that includes insulative spacing structures 160 (individually referred to as “insulative spacing structure 160”) and vias 170 (individually referred to as “via 170”).

In the embodiments of FIG. 1, the metal layer 180 is M0, i.e., the metal layer arranged closest to the FEOL section 110. In other embodiments, the metal layer 180 may be M1, M2, etc. Also, the IC device 100 may include fewer, more, or different components. For instance, the FEOL section 110 may include more transistors, or other semiconductor devices not shown in FIG. 1. Also, the BEOL section 120 may include one or more other metal layers, which may be coupled to at least one of the metal lines 185. The BEOL layer 170 may include a different number of metal lines 185, insulative spacing structures, or vias 170.

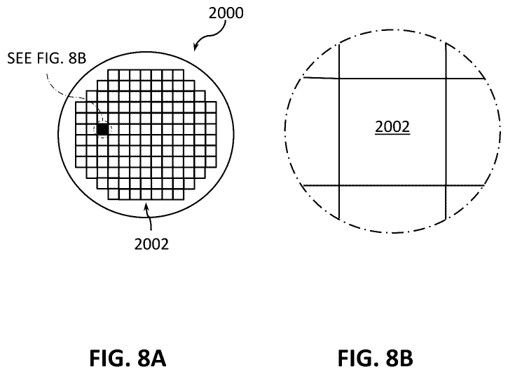

The support structure 115 may be any suitable structure, such as a substrate, a die, a wafer, or a chip, based on which the transistors 117 can be built. The support structure 115 may, e.g., be the wafer 2000 of FIG. 8A, discussed below, and may be, or be included in, a die, e.g., the singulated die 2002 of FIG. 8B, discussed below. In some embodiments, the support structure 115 may be a semiconductor substrate composed of semiconductor material systems including, for example, N-type or P-type materials systems, and, in some embodiments, the channel region 140, described herein, may be a part of the support structure 115. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistors 117 may be built on the support structure 115.

Although a few examples of materials from which the support structure 115 may be formed are described here, any material that may serve as a foundation upon which an IC may be built falls within the spirit and scope of the present disclosure. In various embodiments, the support structure 115 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 115 may provide material “support” in that, e.g., the IC devices/structures described herein are build based on the semiconductor materials of the support structure 115. However, in some embodiments, the support structure 115 may provide mechanical support.

A transistor 117 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. The transistor 117A includes a semiconductor structure that includes a channel region 140A, a source region 143A, and a drain region 147A. The transistor 117A includes a semiconductor structure that includes a channel region 140B, a source region 143B, and a drain region 147B. The channel regions 140A and 140B are collectively referred to as “channel regions 140” or “channel region 140.” The source regions 143A and 143B are collectively referred to as “source regions 143” or “source region 143.” The drain regions 147A and 147B are collectively referred to as “drain regions 147” or “drain region 147.”

The semiconductor structure of each transistor 117 may be at least partially in the support structure 115. The support structure 115 may include a semiconductor material, from which at least a portion of the semiconductor structure is formed. The semiconductor structure of a transistor 117 (or a portion of the semiconductor structure, e.g., the channel region 140) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

Each channel region 140 includes a channel material. The channel material may be composed of semiconductor material systems including, for example, n-type or p-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group Ill of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example n-type transistor embodiments (i.e., for the embodiments where the transistor 117 is an NMOS (N-type metal-oxide-semiconductor) transistor or an n-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm−3), and advantageously below 10¹³ cm⁻³. These materials may be amorphous or polycrystalline, e.g., having a crystal grain size between 0.5 nanometers and 100 nanometers.

For some example p-type transistor embodiments (i.e., for the embodiments where the transistor 117 is a PMOS (P-type metal-oxide-semiconductor) transistor or a p-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In each transistor 117, the source region 143 and the drain region 147 are connected to the channel region 140. The source region 143 and the drain region 147 each includes a semiconductor material with dopants. In some embodiments, the source region 143 and the drain region 147 have the same semiconductor material, which may be the same as the channel material of the channel region 140. A semiconductor material of the source region 143 or the drain region 147 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 143 and the drain region 147 are the same type. In other embodiments, the dopants of the source region 143 and the drain region 147 may be different (e.g., opposite) types. In an example, the source region 143 has n-type dopants and the drain region 147 has p-type dopants. In another example, the source region 143 has p-type dopants and the drain region 147 has n-type dopants. Example n-type dopants include Te, S, As, tin (Sn), Si, Ga, Se, S, In, Al, Cd, chlorine (Cl), iodine (I), fluorine (F), and so on. Example p-type dopants include beryllium (Be), Zn, magnesium (Mg), Sn, P, Te, lithium (Li), sodium (Na), Ga, Cd, and so on.

In some embodiments, the source region 143 and the drain region 147 may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 143 and the drain region 147 may be the regions having dopant concentration higher than in other regions, e.g., higher than a dopant concentration in the channel region 140, and, therefore, may be referred to as “highly doped” (HD) regions.

The channel region 140 may include one or more semiconductor materials with doping concentrations significantly smaller than those of the source region 143 and the drain region 147. For example, in some embodiments, the channel material of the channel region 140 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 143 and the drain region 147, for example below 10¹⁵ cm⁻³ or below 10¹³ cm⁻³. Depending on the context, the term “S/D terminal” may refer to a S/D region or a S/D contact or electrode of a transistor.

Each transistor 117 also includes a source contact over the source region 143 and a drain contact over the drain region 147. In the embodiments of FIG. 1, a source contact or drain contact is a conductive structure 153 in the layer 150. A conductive structure 153, which functions as a source contact or drain contact may be referred to as a TCN. The source contacts and the drain contacts are electrically conductive and may be coupled to source and drain terminals for receiving electrical signals. A source contact or the drain contact includes one or more electrically conductive materials, such as metals. Examples of metals in the source contacts 142 and the drain contacts 146 may include, but are not limited to, Ruthenium (Ru), copper (Cu), cobalt (Co), palladium (Pd), platinum (Pt), nickel (Ni), and so on.

Each transistor 117 also includes a gate that is over or wraps around at least a portion of the channel region 140. The gate of the transistor 117 may include a gate contact (also referred to as “gate electrode”). In the embodiments of FIG. 1, a gate contact is a conductive structure 153 in the layer 150. A conductive structure 153, which functions as a gate contact may be referred to as a GCN. The gate contact may be coupled to a gate terminal that controls gate voltages applied on the transistor 117. The gate electrode may include one or more gate electrode materials, where the choice of the gate electrode materials may depend on whether the transistor 117 is a p-type transistor or an n-type transistor. For a p-type transistor, gate electrode materials that may be used in different portions of the gate electrode may include, but are not limited to, Ru, Pd, Pt, Co, Ni, and conductive metal oxides (e.g., ruthenium oxide). For an n-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate may also include a gate insulator (not show in FIG. 1) that separates at least a portion of the channel region 140 from the gate electrode so that the channel region 140 is insulated from the gate electrode. In some embodiments, the gate insulator may wrap around at least a portion of the channel region 140. The gate insulator may also wrap around at least a portion of the source region 143 or the drain region 147. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The conductive structures 153 are separated by the insulative structures 155 in the layer 150. An insulative structure 155 may include one or more electrical insulators, such as dielectric material, hysteretic material, and so on. In some embodiments, the insulative structures 155 may include the same electrical insulator. In other embodiments, the insulative structures 155 may include different electrical insulators.

As shown in FIG. 1, the transistors 117 are coupled to the metal layer 180 through the vias 170. The metal layer 180 may facilitate controlling operation of the transistors 117 by providing electrical signals to the transistors 117, such as the source contacts, the drain contacts, or the gate contacts. For purpose of illustration, the metal lines 185A and 185D are coupled to the source regions 143, the metal lines 185B and 185E are coupled to the channel regions 140, and the metal lines 185C and 185F are coupled to the drain regions 147. Each metal line 185 is an electrically conductive structure. A metal line 185 may also be referred to as electrically conductive interconnects or interconnects. The metal layer 180 may also be referred to as an electrically conductive interconnect set or an interconnect set. In some embodiments, a metal line 185 includes one or more metal, such as tungsten (W), molybdenum (Mo), ruthenium (Ru), copper (Cu), other metals, or some combination thereof. The metal lines 185 are shown as rectangles in FIG. 1 for purpose of illustration. The metal lines 185 may have different shapes in other embodiments. Some or all of the metal lines 185 may be at different electrical potentials during operation of the IC device 100. The metal lines 185 are arranged in parallel in FIG. 1. A metal line 185 may have a longitudinal axis along the Y axis. The metal line 185 may have a transvers cross-section perpendicular to the longitudinal axis. In some embodiments, the metal lines 185 have the same or similar height, i.e., the dimension along the Z axis.

The metal lines 185 are insulated from each other by the electrical insulator 125. The electrical insulator 125 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. The electrical insulator 125 may be referred to as ILD of the BEOL section 120.

The vias 170 are connected to the transistor 117 and the metal lines 185. Each via 170 is electrically conductive. A via 170 may include a metal, such as tungsten (W), molybdenum (Mo), ruthenium (Ru), copper (Cu), or other metals. Different vias 170 may include different materials. The vias 170 can provide a conductive channel between the transistor 117s and the metal layer 180. In the embodiments of FIG. 1, each via 170 has two ends with one end connected to a transistor 117 and the other end connected to a metal line 185. The vias 170 can provide electrical connections between contacts (e.g., gate contact, source contact, and drain contact) of the transistor 117 and the metal lines 185. The vias 170 that are connected to gate contacts may be referred to as VCGs. The vias 170 that are connected to source contacts and drain contacts may be referred to as VCTs. For purpose of illustration, FIG. 1 shows two vias 170 (i.e., the vias that are connected to the metal lines 185B and 185E) that are VCGs and four vias 170 (i.e., the vias that are connected to the metal lines 185 A, 185C, 185D, and 185F) that are VCTs. In other embodiments, the transistors 117 may be coupled to the metal layer 180 through a different number of vias 170. In other embodiments, the electrical connection between the metal layer 180 and the transistors 117 may be different. Also, the transistors 117 may be coupled to one or more other metal layers. Even though not shown in FIG. 1, the metal layer 180 may be coupled with other devices than the transistor 117, such as diodes, power sources, resistors, capacitors, inductors, sensors, transceivers, receivers, antennas, and so on.

Each via 170 has a portion that is between two adjacent insulative spacing structures 160. The insulative spacing structures 160 provides a shorting margin for the vias 170. Two insulative spacing structures 160 surrounding a via 170 can prevent electrical short between the via 170 and one or more conductive structures 153 that are not connected to the via 170. For instance, a via 170 connected to a gate contact of a transistor is separated from the source contact and drain contact of the transistor by the two insulative spacing structures 160 surrounding the via 170. That way, the gate contact is not shorted to the source contact or drain contact. Without the insulative spacing structures 160, the conductive structures 153 functioning as gate contacts may need to be recessed, so become shorter than adjacent conductive structures to provide the necessary shorting margin. The reduction in the height of the conductive structures 153 can result in higher resistance. Also, the recess can cause variations among the conductive structure 153, which can degrade the performance of the IC device 100.

Each insulative spacing structure 160 includes a spacer 163 and a liner 165. Each spacer 163 is over an insulative structure 155 along the Z axis. Each spacer 163 may be electrically insulative and includes one or more electrical insulators. In some embodiments, a length of a spacer 163 along the X axis is the same or similar as the length of the insulative structure 155 along the X axis. One or more edges of the spacer 163 may be aligned with one or more edges of the insulative structure 155 along the Z axis. An edge of the spacer 163 may be aligned with an edge of a conductive structure 153 along the Z axis. For instance, an edge of the space 163 and an edge of the insulative structure 155 or the conductive structure 153 may be in a straight line. The spacers 163 may be formed based on self-assembly of a diblock copolymer.

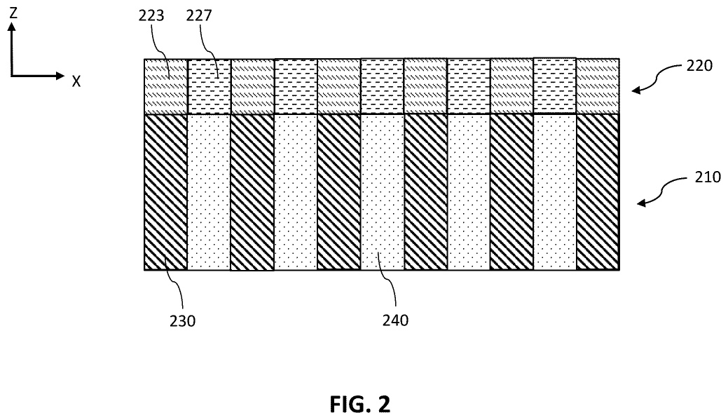

Each liner 165 surrounds a spacer 163 at least partially. A liner 165 may wrap around the corresponding spacer 163 in a plane perpendicular to the Z axis. I For instance, the liner 165 may wrap around one or more side surfaces of the spacer 163 that are perpendicular to the layer 150 or to the support structure 115. Each liner 165 is over a portion of each of two adjacent conductive structures 153, i.e., the two conductive structures 153 between which the insulative structure 155 over the spacer 163 is arranged. Each liner 165 may be electrically insulative and includes one or more electrical insulators. The liners 165 may be formed by depositing one or more electrical insulators onto the surface of the BEOL layer 170. With the liners 165, there can be more shorting margin for the vias 170. Also, material choice for the insulative spacing structures 160 can be independent from the insulative structures 155. In some embodiments, the insulative spacing structures 160 include one or more different materials from the insulative structures 155. Examples of a material in the insulative spacing structures 160 may include silicon oxide (SiO), silicon nitride (SiN), silicon carbide (SiC), silicon oxynitride (SiOₓN_{y}, where x and y are integers), and so on. In some embodiments, the spacers 163 may have a different material from the liners 165. The independence in material choice for the insulative spacing structures 160 may enhance the insulation effect of the insulative spacing structures 160, which can be important for IC devices with tight pitches and limited shorting margins. More details regarding formations of the insulative spacing structures 160 are described below in conjunction with FIGS. 2-5.

FIG. 2 illustrates DSA of a diblock copolymer, according to some embodiments of the disclosure. The diblock copolymer is provided to a top surface of a layer 210. The layer 210 includes a set of conductive structures 230 (individually referred to as “conductive structure 230”) and a set of insulative structures 240 (individually referred to as “insulative structure 240”). An insulative structure 240 includes one or more electrical insulators. Two adjacent conductive structures 230 are separated by an insulative structure 240 and therefore, are insulated from each other. An embodiment of the layer 210 is the layer 150 in FIG. 1.

A conductive structure 230 may functions as a contact of a semiconductor device. For instance, a conductive structure 230 be a conductive structure 153 in FIG. 1. Alternatively, a conductive structure 230 may be a metal line in a BEOL section of an IC device. In some embodiments, different conductive structures 230 (e.g., two adjacent conductive structures 230) may have different electrical potentials or may be coupled to different components of an IC device. For example, a conductive structure 230 may be coupled to a semiconductor device (e.g., transistor, capacitor, diode, etc.) versus another conductive structure 230 may be coupled to a different semiconductor device. For instance, a conductive structure 230 may be coupled to an electrode of a semiconductor device (e.g., a gate electrode, a source contact, or a drain contact of a transistor) versus another conductive structure 230 may be coupled to a different electrode of the same semiconductor device. In some embodiments, some of the conductive structures 230 are GCNs (i.e., gate contacts) and other conductive structures 230 are TCNs (i.e., trench contacts). The GCNs may alternate with the TCNs. A GCN may be connected to a VCG. The VCG is a via-to-gate contact, which may be a via that is connected to the gate electrode of a transistor. A TCN may be connected to a VCT. The VCT is a via-to-contact, which may be a via that is connected to the source contact or drain contact of a transistor.

In some embodiments, the layer 210 may be formed by forming a conductive layer (such as a layer of a metal), forming openings (e.g., trenches) in the conductive layer (e.g., by etching the metal), and providing (e.g., depositing) one or more electrical insulators into the openings to form the insulative structures 240. In some embodiments, the layer 210 may be formed by forming an insulative layer including one or more electrical insulators, forming openings (e.g., trenches) in the insulative layer, and providing (e.g., depositing) one or more metals into the openings to form the conductive structures 230.

A layer 220 is formed through DSA of the diblock copolymer over the layer 210. The layer 220 has an alternating pattern in which structures 223 (individually referred to as “structure 223”) alternatives with structures 227 (individually referred to as “structure 227”). The alternating pattern of the structures 223 and 237 is also referred to as a DSA pattern. The structures 223 and 237 may include two different polymers, such as polymer A and polymer B, the monomers of which are in a diblock copolymer.

In some embodiments, the diblock copolymer may be deposited onto the top surface of the layer 210. The diblock copolymer may include two types of monomers: A and B. The diblock copolymer may have a phase (e.g., a lamellar phase) that has a periodic distribution of A and B. In the embodiment of FIG. 2, the structures 223 include one of the monomers, and the structurers 237 include the other monomer. In an example, the structures 223 include polystyrene (PS), and the structures 227 include poly(methyl methacrylate) (PMMA). In another example, the structures 223 include PMMA, and the structures 227 include PS.

In some embodiments, the DSA of the diblock copolymer may be facilitated by a guiding pattern that can guide microphase separation of the diblock copolymer. The diblock copolymer may self-assembly and form lamellar structures based on the guiding pattern. The guiding pattern may be a topographical guiding pattern, a chemical guiding pattern, or a combination of both. An example topographical guiding pattern may include walls and openings between the walls, and the self-assembly of the diblock copolymer is drive by the physical boundaries.

An example chemical guiding pattern may include sections that have stronger chemical affinity to polymer A than polymer B or sections that have stronger chemical affinity to polymer B than polymer A, and the self-assembly of the diblock copolymer is drive by the differentiated chemical affinities. In an embodiment, the metal in the conductive structures 230 may have stronger chemical affinity to polymer A, and the electrical insulator in the insulative structures 240 may have stronger chemical affinity to polymer A. As a result, the structures 223 are formed on top of the conductive structures 230, and the structures 227 are formed on top of the insulative structures 240.

As shown in FIG. 2, each structure 223 is over a conductive structure 230, and each structure 227 is over an insulative structure 240. In some embodiments, an edge of a structure 223 along the Z axis may be aligned with an edge of the conductive structure 230, which is over the structure 223, along the Z axis. The length of a structure 223 in the direction along the X axis may be the same or similar as the length of a conductive structure 230 in the direction. An edge of a structure 227 along the Z axis may be aligned with an edge of the insulative structure 240, which is over the structure 227, along the Z axis. The length of a structure 227 in the direction along the X axis may be the same or similar as the length of an insulative structure 240 in the direction.

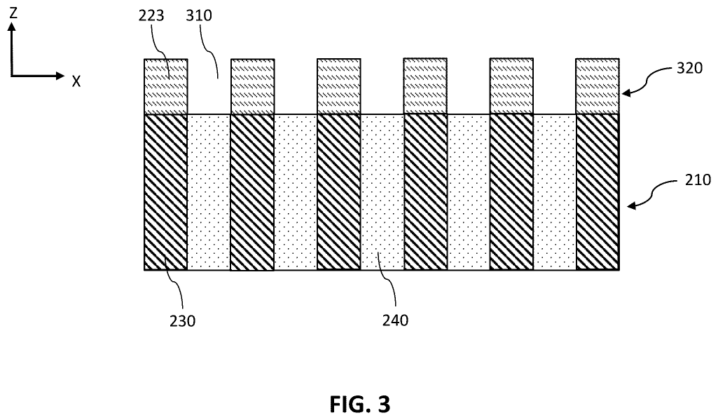

FIG. 3 illustrates formation of openings 310 (individually referred to as “opening 310”) based on a DSA pattern, according to some embodiments of the disclosure. The DSA pattern may be the DSA pattern shown in FIG. 2. The openings 310 may be formed by removing the structures 227 from the layer 210. In some embodiments, the structures 227 are removed through etch, such as selective etch. A rate of etching the structures 227 may be significantly greater than the rate of etching the structures 223. The structures 223 may be barely etched or not etched at all. A new layer 320 is formed. The layer 320 includes the structures 223 and the openings 310. For purpose of illustration, each of the openings 310 is between two adjacent structures 223. In some embodiments, an opening 310 may have a position that is the same or similar as the position of the corresponding structure 227 in FIG. 2. Also, the opening 310 may have one or more same dimensions as the structure 227. For instance, a dimension of the opening 310 along the X axis, Z axis, or Y axis (i.e., the axis perpendicular to the X-Z plane) may be the same as the corresponding dimension of the structure 227. As shown in FIG. 3, the openings 310 and the structures 223 constitute an alternating pattern that is the same or similar to the DSA pattern in FIG. 2.

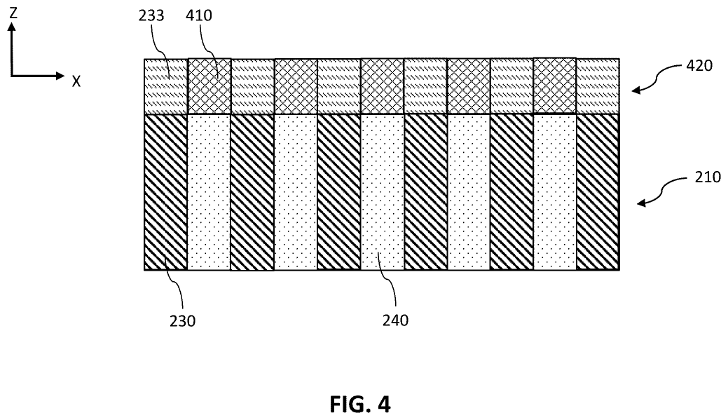

FIG. 4 illustrates formation of spacers 410 (individually referred to as “spacer 410”), according to some embodiments of the disclosure. A spacer 410 may be an embodiment of a spacer 163 in FIG. 1. The spacers 410 are formed in the openings 310 shown in FIG. 3. The spacers 410 and the structures 223 constitute a layer 420, which is over the layer 210. The layer 420 has an alternating pattern of the spacers 410 and the structures 223. The alternating pattern may be the same or similar to the DSA pattern in FIG. 2. A spacer 410 may have a position that is the same or similar as the position of the corresponding structure 227 in FIG. 2. Also, the spacer 410 may have one or more same dimensions as the structure 227. For instance, a dimension of the spacer 410 along the X axis, Z axis, or an axis perpendicular to the X-Z plane may be the same as the corresponding dimension of the structure 227.

In some embodiments, the spacers 410 may be formed by depositing one or more electrical insulators into the openings 310. Each spacer 410 may fill an opening 310. The spacers 410 may be referred to as interlayer dielectric. As shown in FIG. 4, a spacer 410 is over an insulative structure 240 in the direction along the Z axis and is between two adjacent conductive structures 230 in the direction along the X axis. An edge of the spacer 410 that are along the Z axis may be aligned with an edge of the insulative structure 240 or an edge of one of the two adjacent conductive structures 230. A length of the spacer 410 along the X axis may be the same or similar as a length of the insulative structure 240 along the X axis.

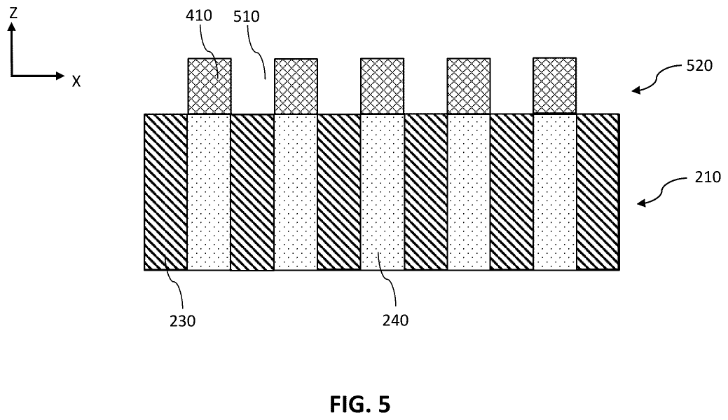

FIG. 5 illustrates formation of openings 510 that separate spacers, according to some embodiments of the disclosure. The openings 510 are formed by removing the structures 223 from the layer 420 shown in FIG. 4. In some embodiments, the structures 223 are removed through etch, such as selective etch. A rate of etching the structures 223 may be significantly greater than the rate of etching the spacers 410. The spacers 410 may be barely etched or not etched at all. A new layer 520 is formed. The layer 520 includes the spacers 410 and the openings 510. An opening 510 may be between two adjacent spacers 410. In some embodiments, an opening 510 may have a position that is the same or similar as the position of the corresponding structure 223 in FIG. 4. Also, the opening 510 may have one or more same dimensions as the structure 223. For instance, a dimension of the opening 510 along the X axis, Z axis, or an axis perpendicular to the X-Z plane may be the same as the corresponding dimension of the structure 223. As shown in FIG. 5, the openings 510 and the spacers 410 constitute a layer 520. The layer 520 has an alternating pattern of the openings 510 and the spacers 410 constitute a layer 520. The alternating pattern may be the same or similar to the DSA pattern in FIG. 2.

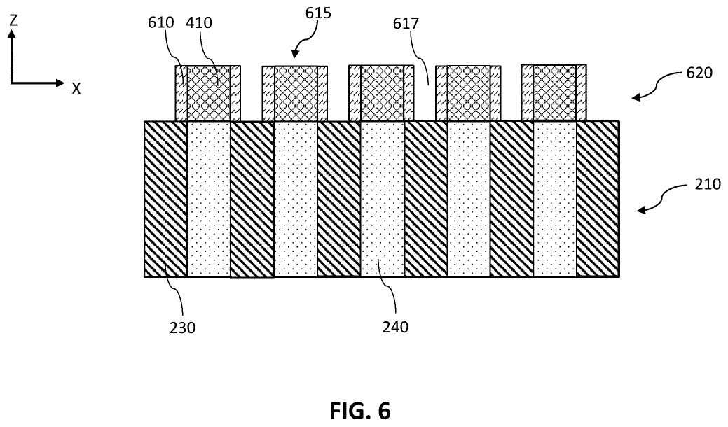

FIG. 6 illustrates formation of liners 610 (individually referred to as “liner 610”), according to some embodiments of the disclosure. A liner 610 may be formed by depositing a dielectric material onto the top surface of the layer 210. Each liner 610 surrounds the side surfaces of a spacer 410. The liner 610 and the spacer 410 forms an insulative structure 615. Two adjacent insulative structures 615 are separated by an opening 617. The insulative structures 615 and openings 617 constitute a new layer 620. In some embodiments, a spacer 410 is over an insulative structure 240, and the liner of the spacer 410 is over the two metal lines between which the insulation structure 240 is located. As the formation of the liners 610 and the spacers 410 may be separate processes, the material choice for the liners 610 and the spacers 410 can be independent. In some embodiments, the liners 610 may have a different material from the spacers 410. A liner 610 may be an embodiment of a liner 165 in FIG. 1. An insulative structures 615 may be an embodiment of an insulative spacing structure 160 in FIG. 1.

FIG. 7 illustrates vias 710 that are separated from conductive structures 230 through spacers 410 and liners 610, according to some embodiments of the disclosure. For purpose of illustration, FIG. 7 shows two vias 710 (individually referred to as “via 710”). In other embodiments, more than two vias may be present. A portion of each via 710 is placed between two adjacent insulative structures 615, each of which includes a spacer 410 that is at least partially wrapped around by a liner 610. Each via 710 is connected to a conductive structure 230 located between the two spacers 410 in the two adjacent insulative structures 615. The via 710 may be at the same electrical potential as the conductive structure 230. The via 710 is insulated from other conductive structures 230 (e.g., conductive structures 230 that are adjacent to the conductive structure 230 connected to the via 710) through insulative structures 615. Given the presence of the insulative structures 615, the via 710 can be at a different electrical potential from other conductive structures 230 despite that all the conductive structures 230 can have the same height along the Z axis.

The vias 710 may be at different electrical potentials from each other. In some embodiments, the vias 710 may be coupled to different components of an IC device. For example, one of the vias 710 may be connected to a semiconductor device (e.g., transistor, capacitor, diode, etc.) versus the other via 720 may be connected to a different semiconductor device. For instance, one of the vias 710 may be connected to an electrode of a semiconductor device (e.g., a gate electrode, a source contact, or a drain contact of a transistor) versus the other via 720 may be connected to a different electrode of the same semiconductor device.

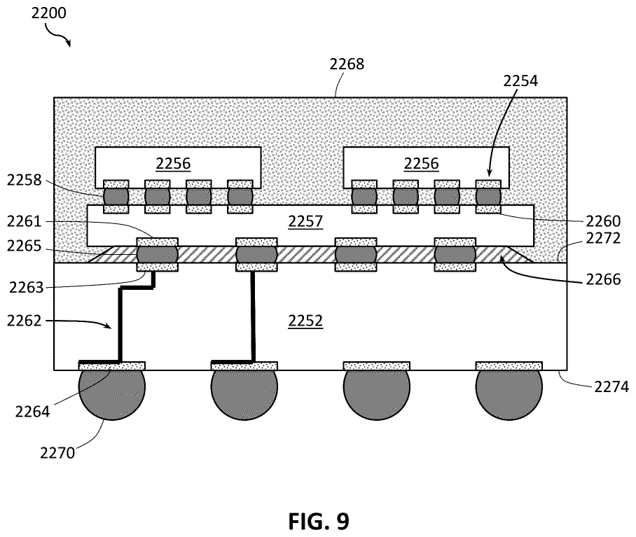

FIGS. 8A-8B are top views of a wafer 2000 and dies 2002 that may include DSA-based spacers and liners, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 9. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including DSA-based spacers and liners as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include DSA-based spacers and liners as disclosed herein may take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 9 is a side, cross-sectional view of an example IC package 2200 that may include one or more IC devices having DSA-based spacers and liners, according to some embodiments of the disclosure. In some embodiments, the IC package 2200 may be a system-in-package (SiP).

As shown in FIG. 9, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 9 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 9 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

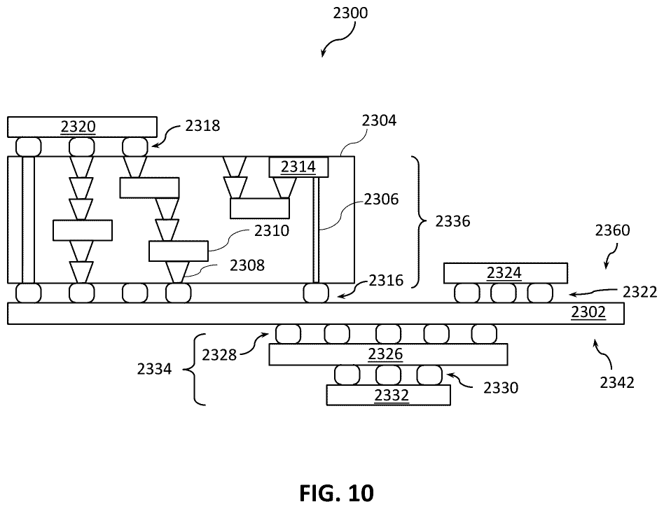

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 9 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 10.

The dies 2256 may take the form of any of the embodiments of the die 2002 discussed herein and may include any of the embodiments of an IC device having DSA-based spacers and liners. In embodiments in which the IC package 2200 includes multiple dies 2256, the IC package 2200 may be referred to as a multi-chip package. Importantly, even in such embodiments of an MCP implementation of the IC package 2200, DSA-based spacers and liners may be provided in a single chip, in accordance with any of the embodiments described herein. The dies 2256 may include circuitry to perform any desired functionality. For example, one or more of the dies 2256 may be ESD protection dies, including DSA-based spacers and liners as described herein, one or more of the dies 2256 may be logic dies (e.g., silicon-based dies), one or more of the dies 2256 may be memory dies (e.g., high bandwidth memory), etc. In some embodiments, any of the dies 2256 may include DSA-based spacers and liners, e.g., metal lines as discussed above; in some embodiments, at least some of the dies 2256 may not include any III-N diodes with n-doped wells and capping layers.

The IC package 2200 illustrated in FIG. 9 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 9, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 10 is a cross-sectional side view of an IC device assembly 2300 that may include components having one or more IC devices implementing DSA-based spacers and liners, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing DSA-based spacers and liners in accordance with any of the embodiments disclosed herein; e.g., any of the IC packages discussed below with reference to the IC device assembly 2300 may take the form of any of the embodiments of the IC package 2200 discussed above with reference to FIG. 9 (e.g., may include DSA-based spacers and liners in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 10 includes a package-on-interposer structure 2236 coupled to the first face 2340 of the circuit board 2302 by coupling components 2316. The coupling components 2316 may electrically and mechanically couple the package-on-interposer structure 2236 to the circuit board 2302, and may include solder balls (e.g., as shown in FIG. 10), male and female portions of a socket, an adhesive, an underfill material, and/or any other suitable electrical and/or mechanical coupling structure.

The package-on-interposer structure 2236 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 8B), an IC device (e.g., the IC device of FIGS. 1-2), or any other suitable component. In particular, the IC package 2320 may include DSA-based spacers and liners as described herein. Although a single IC package 2320 is shown in FIG. 10, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 10, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing DSA-based spacers and liners as described herein may also be implemented in/on the interposer 2304. The package-on-interposer structure 2236 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 10 includes a package-on-package structure 2234 coupled to the second face 2342 of the circuit board 2302 by coupling components 2328. The package-on-package structure 2234 may include an IC package 2326 and an IC package 2332 coupled together by coupling components 2

such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2234 may be configured in accordance with any of the package-on-package structures known in the art.

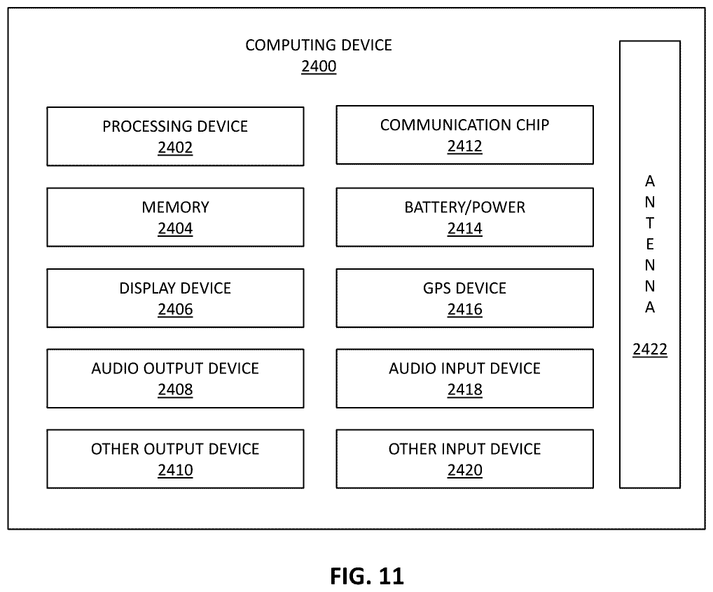

FIG. 11 is a block diagram of an example computing device 2400 that may include one or more components with one or more IC devices having DSA-based spacers and liners, according to some embodiments of the disclosure. For example, any suitable ones of the components of the computing device 2400 may include a die (e.g., the die 2002 of FIG. 8B) including DSA-based spacers and liners, according to some embodiments of the disclosure. Any of the components of the computing device 2400 may include an IC device (e.g., the IC device in FIG. 1) and/or an IC package (e.g., the IC package 2200 of FIG. 9). Any of the components of the computing device 2400 may include an IC device assembly (e.g., the IC device assembly 2300 of FIG. 10).

A number of components are illustrated in FIG. 11 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 11, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408 but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a layer, including a gate contact of a transistor, an additional contact of the transistor, and an electrical insulator between the gate contact and the additional contact; a first via over the layer in a direction, the first via connected to the gate contact; a second via over the layer in the direction, the second via connected to the additional contact; and an insulative structure over the layer in the direction, the insulative structure including a first insulative structure and a second insulative structure at least partially surrounding the first insulative structure, where the gate contact is in parallel with the additional contact, the gate contact is separated from the second via by the insulative structure, and a dimension of gate contact in the direction is the same or substantially the same as a dimension of the additional contact in the direction.

Example 2 provides the IC device according to example 1, where the first insulative structure is over the electrical insulator, and at least a portion of the second insulative structure is over the gate contact or the additional contact.

Example 3 provides the IC device according to example 1 or 2, where an edge of the first insulative structure is aligned with an edge of the gate contact or an edge of the additional contact in the direction.

Example 4 provides the IC device according to any of the preceding examples, where the insulative structure includes an electrical insulator that is different from the electrical insulator between the gate contact and the additional contact.

Example 5 provides the IC device according to any of the preceding examples, where the first insulative structure and the second insulative structure include different materials.

Example 6 provides the IC device according to any of the preceding examples, further including an additional insulative structure over the layer, where the additional contact is separated from the first via by the additional insulative structure.

Example 7 provides the IC device according to any of the preceding examples, where the gate contact is over at least part of a channel region of the transistor, and the additional contact is over at least part of a source region or a drain region of the transistor.

Example 8 provides an IC device, including a first conductive structure; a second conductive structure in parallel with the first conductive structure in a direction, where a dimension of the second conductive structure in the direction is the same or substantially the same as a dimension of the first conductive structure in the direction; an insulative structure including a first portion and a second portion, where the first portion is over the first conductive structure, and a second portion is over the second conductive structure; and a via connected to the first conductive structure, the via separated from the second conductive structure by the insulative structure.

Example 9 provides the IC device according to example 8, where the second conductive structure is separated from the first conductive structure by an electrical insulator, the insulative structure further includes a third portion, and the third portion is over the electrical insulator.

Example 10 provides the IC device according to example 9, where an edge of the third portion is aligned with an edge of the first conductive structure in the direction.

Example 11 provides the IC device according to example 10, where another edge of the third portion is aligned with an edge of the second conductive structure in the direction.

Example 12 provides the IC device according to example 9 or 10, where the insulative structure includes a different material from the electrical insulator.

Example 13 provides the IC device according to any one of examples 9-12, where the third portion includes a different material from the first portion or the second portion.

Example 14 provides the IC device according to any one of examples 8-13, further including an additional insulative structure between the second conductive structure and the first via.

Example 15 provides a method for forming an IC device, including forming a lamellar pattern over a layer, the layer including a first conductive structure and a second conductive structure, the lamellar pattern including first lamellar structures alternating with second lamella structures; forming a plurality of insulative structures based on the lamellar pattern, an individual insulative structure including a first insulative structure and a second insulative structures, the second insulative structure wrapping around at least part of the first insulative structure; providing a first via between two of the plurality of insulative structures, the first via connected to the first conductive structure; and providing a second via between another two of the plurality of insulative structures, the second via connected to the second conductive structure.

Example 16 provides the method according to example 15, where forming a plurality of first insulative structures based on the lamellar pattern includes forming a plurality of first insulative structures, which includes the first insulative structure, over the layer based on the lamellar pattern; and after forming the plurality of first insulative structures, forming a plurality of second insulative structures, which includes the second insulative structure.

Example 17 provides the method according to example 16, where forming the plurality of second insulative structures includes depositing an insulative material onto the layer.

Example 18 provides the method according to any one of examples 15-17, where the first insulative structure and the second conductive structure include different materials.

Example 19 provides the method according to any one of examples 15-18, where the first via is further connected to a gate electrode of a transistor.

Example 20 provides the method according to example 19, where the second via is further connected to a conductive contact of a source region or a drain region of the transistor.

Example 21 provides an IC package, including the IC device according to any one of examples 1-14; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-14 may include, or be a part of, at least one of a memory device, a computing device, a wearable device, a handheld electronic device, and a wireless communications device.

Example 24 provides an electronic device, including a carrier substrate; and one or more of the IC devices according to any one of examples 1-14 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides the method according to any one of examples 15-20, further including processes for forming the IC device according to any one of claims 1-14.

Example 35 provides the method according to any one of examples 15-20, further including processes for forming the IC package according to any one of the claims 21-23.

Example 36 provides the method according to any one of examples 15-20, further including processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a layer, comprising:
a gate contact of a transistor,
an additional contact of the transistor, and
an electrical insulator between the gate contact and the additional contact;
a first via over the layer in a direction, the first via connected to the gate contact;
a second via over the layer in the direction, the second via connected to the additional contact; and
an insulative structure over the layer in the direction, the insulative structure comprising a first insulative structure and a second insulative structure at least partially surrounding the first insulative structure,
wherein the gate contact is in parallel with the additional contact, the gate contact is separated from the second via by the insulative structure, and a dimension of the gate contact in the direction is the same or substantially the same as a dimension of the additional contact in the direction.

2. The IC device according to claim 1, wherein:
the first insulative structure is over the electrical insulator, and
at least a portion of the second insulative structure is over the gate contact or the additional contact.

3. The IC device according to claim 1, wherein an edge of the first insulative structure is aligned with an edge of the gate contact or an edge of the additional contact in the direction.

4. The IC device according to claim 1, wherein the insulative structure comprises an electrical insulator that is different from the electrical insulator between the gate contact and the additional contact.

5. The IC device according to claim 1, wherein the first insulative structure and the second insulative structure comprise different materials.

6. The IC device according to claim 1, further comprising:
an additional insulative structure over the layer, wherein the additional contact is separated from the first via by the additional insulative structure.

7. The IC device according to claim 1, wherein the gate contact is over at least part of a channel region of the transistor, and the additional contact is over at least part of a source region or a drain region of the transistor.

8. An integrated circuit (IC) device, comprising:
a first conductive structure;
a second conductive structure in parallel with the first conductive structure in a direction, wherein a dimension of the second conductive structure in the direction is the same or substantially the same as a dimension of the first conductive structure in the direction;
an insulative structure comprising a first portion and a second portion, wherein the first portion is over the first conductive structure, and a second portion is over the second conductive structure; and
a via connected to the first conductive structure, the via separated from the second conductive structure by the insulative structure.

9. The IC device according to claim 8, wherein:
the second conductive structure is separated from the first conductive structure by an electrical insulator,
the insulative structure further comprises a third portion, and
the third portion is over the electrical insulator.

10. The IC device according to claim 9, wherein an edge of the third portion is aligned with an edge of the first conductive structure in the direction.

11. The IC device according to claim 10, wherein another edge of the third portion is aligned with an edge of the second conductive structure in the direction.

12. The IC device according to claim 9, wherein the insulative structure comprises a different material from the electrical insulator.

13. The IC device according to claim 9, wherein the third portion comprises a different material from the first portion or the second portion.

14. The IC device according to claim 8, further comprising:
an additional insulative structure between the second conductive structure and the first via.

15. A method for forming an integrated circuit (IC) device, comprising:
forming a lamellar pattern over a layer, the layer comprising a first conductive structure and a second conductive structure, the lamellar pattern comprising first lamellar structures alternating with second lamella structures;
forming a plurality of insulative structures based on the lamellar pattern, an individual insulative structure comprising a first insulative structure and a second insulative structures, the second insulative structure wrapping around at least part of the first insulative structure;
providing a first via between two of the plurality of insulative structures, the first via connected to the first conductive structure; and
providing a second via between another two of the plurality of insulative structures, the second via connected to the second conductive structure.

16. The method according to claim 15, wherein forming a plurality of first insulative structures based on the lamellar pattern comprises:
forming a plurality of first insulative structures, which includes the first insulative structure, over the layer based on the lamellar pattern; and
after forming the plurality of first insulative structures, forming a plurality of second insulative structures, which includes the second insulative structure.

17. The method according to claim 16, wherein forming the plurality of second insulative structures comprises:
depositing an insulative material onto the layer.

18. The method according to claim 15, wherein the first insulative structure and the second conductive structure include different materials.

19. The method according to claim 15, wherein the first via is further connected to a gate electrode of a transistor.

20. The method according to claim 19, wherein the second via is further connected to a conductive contact of a source region or a drain region of the transistor.
